(19) United States
(12) Patent Application Publication
(10) Pub. No.: US 2015/0375997 A1
(43) Pub. Date: Dec. 31, 2015

(54) HIERARCHICAL STRUCTURED SURFACES

(71) Applicant: Massachusetts Institute of Technology, (US)

(72) Inventors: Kuang-Han Chu, Cambridge, MA (US); Ryan Enright, Whitestone, NY (US); Evelyn N. Wang, Cambridge, MA (US)

(21) Appl. No.: 13/827,874

(22) Filed: Mar. 14, 2013

Related U.S. Application Data
(60) Provisional application No. 61/654,944, filed on Jun. 3, 2012.

(51) Int. Cl. B81C 1/00; C25D 5/16; C25D 5/12; C25D 13/02

(52) U.S. Cl. CPC B81C 1/0069; C25D 13/02; C25D 5/16; C25D 5/12; B81C 1/00015; B81C 1/00373

(57) ABSTRACT

A hierarchical structured surface can have high heat transfer performance during a phase change process. Using hierarchically structured surfaces, an enhancement in critical heat flux (CHF) of ˜160% or higher on a microstructured surface can be obtained.

### CLAIM OF PRIORITY

This application claims the benefit of prior U.S. Provisional Application No. 61/654,944, filed on Jun. 3, 2012, which is incorporated by reference in its entirety.

### GOVERNMENT SPONSORSHIP

This invention was made with government support under Contract No. FA9550-11-1-0059 awarded by the Air Force Office of Scientific Research. The government has certain rights in this invention.

### TECHNICAL FIELD

The present invention relates to hierarchical structured surfaces.

### BACKGROUND

Methods to extend the critical heat flux (CHF), at which the nucleate pool boiling regime transitions to the film boiling regime, have been studied extensively owing to its significant practical importance in areas such as thermal energy conversion in power generation and high performance thermal management systems. Pool boiling on microstructured surfaces can demonstrate high critical heat flux (CHF) which can be modeled to predict CHF on structured surfaces.

### SUMMARY

In general, a hierarchical structured surface can have high heat transfer performance during a phase change process. A hierarchical surface is a structured surface that demonstrates roughness features with 2 or more distinct length scales, such as, nanoscale (about 1 to 100 nanometers) structures on microscale (about 1 to 100 micrometers) structures. Using hierarchically structured surfaces, an enhancement in critical heat flux (CHF) of ˜160% or higher on the microstructured surfaces can be obtained. The fabrication process used for making the structures can be CMOS-compatible and can be integrated into semiconductor processing. A the structures can be CMOS-compatible and can be integrated into semiconductor processing. A simple force-balance-based model for CHF can be developed and can show excellent agreement with the experimental observations and identifies roughness as the key parameter to increase CHF. Based on the model predication, a potential surface design to achieve ultra high CHF can be developed. This study shows exciting new insights into achieving high CHF with microstructures or micro/nano (hierarchical) structures and can provide design guidelines for new surface technologies with high heat removal capability for advanced thermal management.

In one aspect, a method of increasing heat removal capability of a surface can include increasing surface roughness of a surface having a plurality of microstructured or micro/nano features to enhance surface wettability, whereby the critical heat flux of the surface is increased by at least 150%. The surface roughness can have nanoscale dimensions. In certain circumstances, the critical heat flux of the surface is increased by at least 160%, at least 180%, or at least 200%. In certain embodiments, the surface can include a material selected from the group consisting of silicon, silica, copper, copper oxide and aluminum. In certain circumstances, the silica surface is modified by electrophoretic deposition (EPD) of a plurality of silica nanoparticles. In other circumstances, the method can include applying a surface modifying layer on at least a portion of surface, for example, contact printing the surface with a surface modifying compound, such as a hydrophobic silane. This method can realize a surface that can sustain very high heat fluxes, while also achieving high heat transfer coefficients by lowering the superheat required to achieve a certain bubble density on the boiling surface.

In another aspect, a structure can include a surface having a plurality of microstructured and/or nanostructured or hierarchically structured features and a hydrophilic surface roughening layer suitable to enhance surface wettability, whereby the critical heat flux of the surface is increased by at least 150%. The surface roughening layer can have nanoscale dimensions. In certain embodiments, the critical heat flux can be at least 200 W/cm², at least 210 W/cm², at least 220 W/cm², at least 230 W/cm² or at least 240 W/cm².

In certain other embodiments, the microstructured features can include a plurality of micropillars. Each of the plurality of micropillars can have a diameter of 5 to 10 micrometers, a height of 10 to 20 micrometers, and neighboring micropillars of the plurality have center-to-center spacings of 5 to 15 micrometers.

In certain circumstances, the surface can have a roughness of at least 3, for example, at least 5, at least 8, at least 9, or at least 13.

In certain embodiments, a portion of the surface can include a surface modifying layer including a surface modifying compound, for example, a hydrophobic silane.

Other features, objects, and advantages will be apparent from the description and drawings, and from the claims.

### BRIEF DESCRIPTION OF THE DRAWINGS

FIGS. 1A-1F represent scanning electron micrographs (SEMs) of the fabricated silicon microstructured surfaces.

FIG. 2 represents a schematic depiction of the experimental pool boiling setup with cartridge heaters in the copper block to heat the sample and in-line thermocouples to accurately determine the heat flux and surface temperature.

FIG. 3 represents a graph depicting boiling curves for smooth and micro-structured surfaces detailed in Table I.

FIG. 4 represents a schematic diagram of horizontal forces acting on the vapor bubble on a structured surface.

FIG. 5 represents a graph depicting experimental and model results of CHF for silicon microstructured surfaces.

FIGS. 6A and 6B represent micrographs of hierarchical structures.

FIG. 7 represents a flow diagram for producing low surface energy spots.

FIGS. 8A and 8B represent micrographs of hierarchical surfaces having surface functionalization.

FIG. 9 represents a graph depicting boiling curves for a microstructured surface (CHF ˜180 W/cm²) compared to the same microstructured surface coated with nanostructures, i.e., hierarchical (CHF ˜236 W/cm²).

FIGS. 10A-10F represent SEMs of the fabricated silica and CuO-based hierarchical surfaces.

FIG. 11 represents a graph depicting boiling curves for smooth and micro-structured surfaces detailed in Table II.

FIG. 12 a graph depicting experimental and model results of CHF for microstructured, EPD-coated SiO₂, and CuO hierarchical surfaces.

### DETAILED DESCRIPTION

Thermal management with two-phase cooling has received significant interest for high flux applications including concentrated photovoltaics, GaN power amplifiers, and integrated circuits. See, for example, D. C. Price, “A review of selected thermal management solutions for military electronic systems,” IEEE Trans. Compon. Packag. Technol., vol. 26, pp. 26-39 March 2003 2003, T. W. Kenny, et al., “Advanced Cooling Technologies for Microprocessorsf,” Int. J. High Speed Electron. Syst, vol. 16, pp. 301-313, 2006, J. R. Thome, “The New Frontier in Heat Transfer: Microscale and Nanoscale Technologies,” Heat Transfer Eng., vol. 27, pp. 1-3, 2006, and E. Pop, “Energy dissipation and transport in nanoscale devices,” Nano Res., vol. 3, pp. 147-169, 2010, each of which are incorporated by reference in its entirety. The critical heat flux (CHF) represents the operational limit in a two-phase (boiling) heat transfer system marking the point when a vapor film will begin to cover the heated surface, significantly reducing heat transfer efficiency. Therefore, methods to extend CHF have been studied extensively owing to its significant practical importance in high performance thermal management systems. See, for example, S. G. Kandlikar, “A Theoretical Model to Predict Pool Boiling CHF Incorporating Effects of Contact Angle and Orientation,” J. Heat Transfer, vol. 123, pp. 1071-1079, 2001, E. Forrest, et al., “Augmentation of nucleate boiling heat transfer and critical heat flux using nanoparticle thin-film coatings,” Int. J. Heat Mass Transfer, vol. 53, pp. 58-67, 2010, and C. H. Li and G. P. Peterson, “Experimental study of enhanced nucleate boiling heat transfer on uniform and modulated porous structures,” FHMT, vol. 1, p. 023007, 2010, each of which is incorporated by reference in its entirety. Recent efforts have focused on pushing the limits of CHF by improving surface wettability using decreased feature sizes to nanometer length scales (˜100 nm). While CHF values of ˜200 W/cm² with water have been reported, these nanostructures were fabricated with materials (e.g., ZnO, Cu) or required fabrication processes (e.g., anodic oxidation, electroless etching) that are not compatible with CMOS processing. See, for example, R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, and H. S. Ahn, et al., “Effect of liquid spreading due to nano/microstructures on the critical heat flux during pool boiling,” Appl. Phys. Lett., vol. 98, p. 071908 2011, each of which is incorporated by reference in its entirety. In addition, these nanostructured surfaces were not optimized due to the limited understanding of the role of roughness-augmented wettability on CHF.

In this work, silicon microstructures alone (≧5 μm) fabricated using standard MEMS processing can exhibit critical heat fluxes q″_{CHF}>200 W/cm² are achievable. Furthermore, an analytical force-balance model was extended to explain the CHF enhancement. The excellent agreement found between the model and experimental data supports the idea that roughness-amplified capillary forces are responsible for CHF enhancement on structured surfaces. The work suggests that the ultra high heat removal capability (>250 W/cm²) with structured surfaces using CMOS-compatible processing is possible.

The structure can have columns, pillars, channels and other microstructures, or combinations thereof, which can be patterned or grown from a substrate. For example, micropillars can be patterned using projection lithography, and etched in silicon with deep reactive ion etching (DRIE), or other microstructures can be built. In general, the microstructured features have dimensions of 1 micrometer to 20 micrometers and can be periodic structures having spacing of 1 micrometer to 20 micrometers between features.

Further surface roughness can be introduced by growing nanostructures or depositing a layer of nanoparticles on the surface. The nanostructures can be grown on a silicon or other metal surface (e.g., copper or aluminum) by oxidation or etching or a combination of both etching and oxidation. The nanoparticles can be deposited on a silicon or other metal surface (e.g., copper or aluminum) by deposition by chemical vapor deposition, spin-coating or dip coating. The roughness features can have dimensions of approximately 1 μm or smaller, 500 nm or smaller, 250 nm or smaller, or 100 nm or smaller.

Regions of the surface (spots, portions or areas of 5%, 10%, 20%, 30%, 40%, 50% or more of the total surface area), can have altered surface characteristics by applying a surface modifying layer. The surface modifying layer can include a hydrophobic material, such as a polymer or self-assembled monolayer, placed directly a portion of the surface. For example, a silane or a thiol can be assembled on a surface. The hydrophobic material can be a surface modifying compound, for example, a hydrophobic polymer, hydrophobic thiol, hydrophobic carboxylic acid or hydrophobic silane, can include hydrocarbon (e.g., a saturated hydrocarbon) groups, halohydrocarbon groups (e.g., a saturated fluorohydrocarbon), or halocarbon groups (e.g., a perfluorinated alkyl group). In certain examples, the surface modifying compound can be trichloro(1H,1H,2H,2H-perfluorooctyl) silane, (tridecafluoro-1,1,2,2-tetrahydrooctyl)-1-trichlorosilane, (1H,1H,2H,2H-perfluorodecyl acrylate), a Teflon amorphous fluoropolymer resin, or an alkyl or fluoroalkyl thiol deposited by appropriate techniques. The surface modifying compound can have C₂-C₁₈ groups that can be fluorinated to varying degrees.

### Microstructured Silicon Surfaces

### Fabrication and Boiling Setup

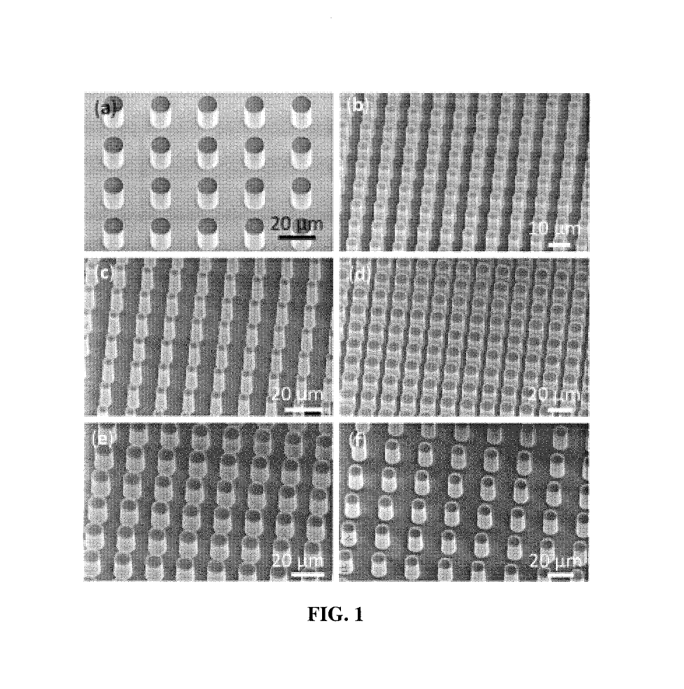

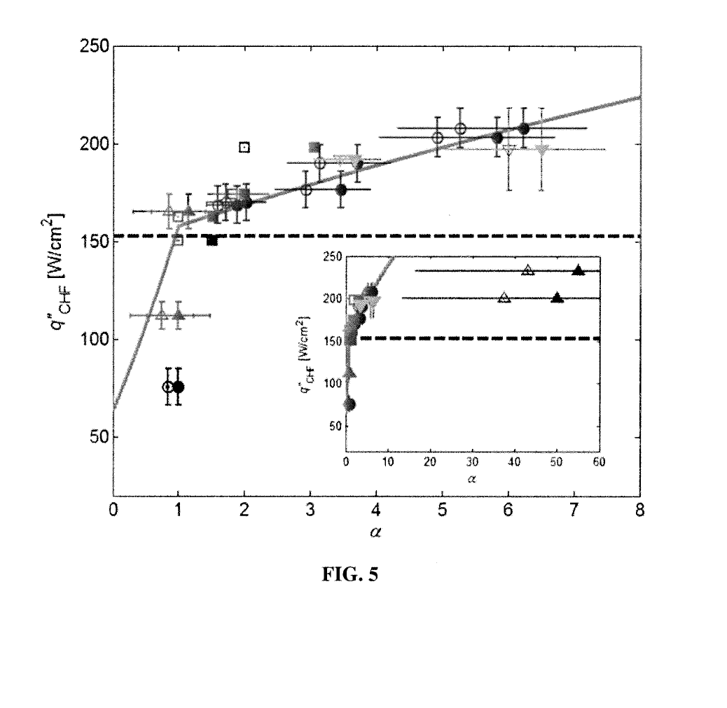

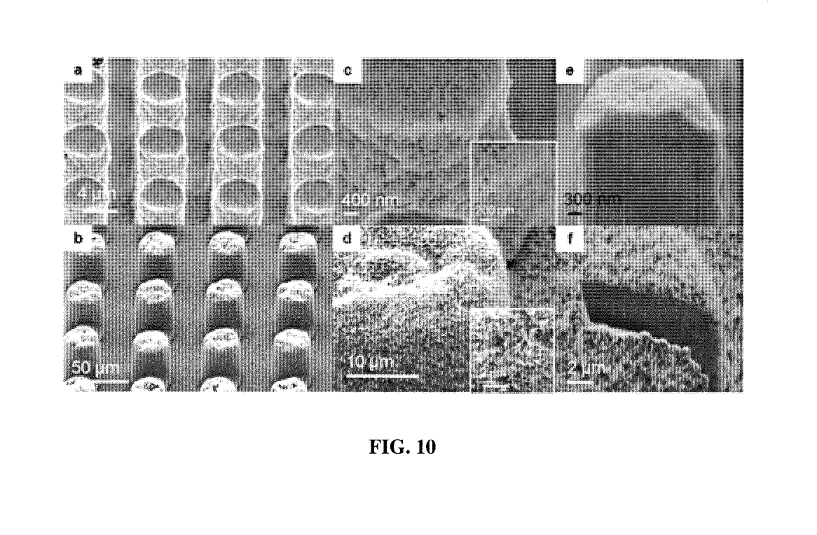

Microstructured surfaces with various roughness r, defined as the ratio of the true area in contact with the liquid to the projected area, were fabricated using MEMS processing on silicon (FIG. 1). The micropillars were patterned using projection lithography, and etched in silicon with deep reactive ion etching (DRIE). The micropillars with diameter of 5-10 μm, center-to-center spacings of 5-15 μm, and heights of 10-20 μm were designed to ensure wicking behaviors. See, for example, J. Bico, et al., “Rough wetting,” Europhysics Letters, vol. 55, pp. 214-220, 2001, which is incorporated by reference in its entirety. Details of the pillar geometries fabricated are listed in Table I. A 300 nm thick thermal oxide layer was subsequently grown to enhance surface wettability. Finally, the etched wafers were diced into samples measuring 2×2 cm, which is large enough to be considered representative of an infinite plate and of comparable size to high heat flux electronic components. See, for example, T. G. Theofanous, et al., “The boiling crisis phenomenon Part I: nucleation and nucleate boiling heat transfer,” Exp. Therm. Fluid Sci., vol. 26, pp. 775-792, 2002 and M.-C. Lu, et al., “Critical heat flux of pool boiling on Si nanowire array-coated surfaces,” Int. J. Heat Mass Transfer, vol. 54, p. Int. J. Heat Mass Transfer, 2011, each of which is incorporated by reference in its entirety. Smooth oxidized samples were also prepared as benchmarks for comparison. Referring to FIG. 1, scanning electron micrographs (SEMs) of the fabricated silicon microstructured surfaces show the pillars have heights of 10 μm (FIG. 1A) and 20 μm (FIGS. 1B-1F); center-to-center spacings of 15 μm (FIGS. 1A and 1F), 5 μm (FIGS. 1B and 1D), and 10 μm (FIGS. 1C and 1E); and diameters of 5 μm (FIGS. 1B and 1C) and 10 μm (FIGS. 1A, 1D-1F).

TABLE I
Geometric parameters of the micropillar arrays. The units of height,
diameter and (center-to-center) spacing are in microns. The
roughness of contact line, r, and solid fraction, φ, are calculated by:
r = 1 + πd h(π/2)/(d + s)² and φ = (πd²/4)/(d + s)², respectively.

| Sample No. | Height (h) | Diameter (d) | Spacing (s) | r | φ |
|---|---|---|---|---|---|
| S1 | 10 | 10 | 15 | 1.790 | 0.126 |
| S2 | 20 | 10 | 15 | 2.579 | 0.126 |
| S3 | 20 | 5 | 10 | 3.193 | 0.087 |
| S4 | 20 | 10 | 10 | 3.467 | 0.196 |
| S5 | 20 | 10 | 5 | 5.386 | 0.349 |
| S6 | 20 | 5 | 5 | 5.935 | 0.196 |

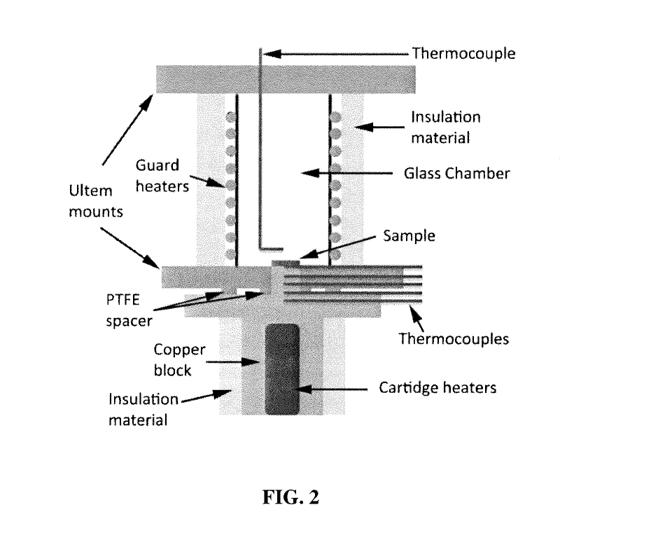

FIG. 2 shows the pool boiling setup which consists of an oxygen-free copper block and a tempered glass chamber fixed at both ends by Ultem mounts. Five cartridge heaters were imbedded in the copper block allowing for a maximum power of 1400 W (350 W/cm²). Five in-line K-type thermocouples (KMQSS-020, OMEGA) were inserted into the center axis of the copper block with the topmost thermocouple located right beneath the sample to accurately determine the heat flux from the linear temperature gradient using Fourier's law. Note that the flux area of the copper block matched the structured sample area (2×2 cm). A sheathed K-type thermocouple (KQSS-18U-12, OMEGA) was positioned 2 cm above the mounted sample to monitor the pool temperature. In the experiments, temperature was recorded with a thermocouple logger (18200-75, Cole-Parmer). To minimize losses, the chamber was wrapped in guard heaters and a layer of dense fiber glass insulation allowing the pool to be maintained at saturation temperature during the experiment. The microstructured surfaces were bonded to the copper block using solder to ensure good attachment with minimal thermal resistance.

Before experiments, the samples were bonded to the copper block using solder paste (Delta 717D, Qualitek) to ensure good attachment with minimal thermal resistance. Note that a 1 thick copper layer was deposited on the back side of the samples to facilitate attachment to the boiling setup. For all tests, degassed, high purity water (CHROMASOLV for HPLC, Sigma-Aldrich) was used to avoid premature bubble formation and minimize surface contamination.

### Experimental Results

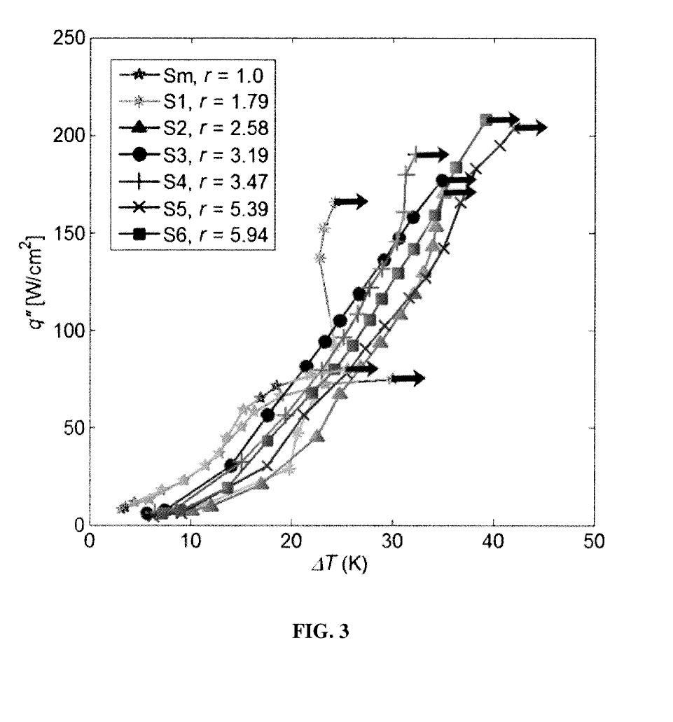

The heat flux q″ as a function of wall superheat ΔT=T_{w}−Tₛₐₜ, where T_{w} is the heated surface temperature and Tₛₐₜ is the saturation temperature, for the smooth and microstructured SiO₂ surfaces are shown in FIG. 3. Referring to FIG. 3, the boiling curves on the smooth (R=1) and micro-structured (R>1) surfaces detailed in Table I. The arrows indicate the CHF condition. The boiling curves show a clear trend of increasing CHF with surface roughness due to roughness-augmented capillary force. The maximum uncertainty of the heat flux and temperature measurements was ˜5.6% and 1.8 K, respectively. Note that in the calculation of the roughness, the scalloped features on the sidewall of micropillars were accounted for by multiplying the pillar height by a factor of π/2. See, for example, R. Xiao, et al., “Prediction and Optimization of Liquid Propagation in Micropillar Arrays,” Langmuir, vol. 26, pp. 15070-15075, 2010, which is incorporated by reference in its entirety. Compared with the results on the smooth surface (Sm), the boiling curves showed a significant enhancement in CHF on the structured surfaces (S1-S6). A CHF of 207.9±9.9 W/cm², which is comparable to the highest CHF value reported in previous studies on nanostructured surfaces (R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, H. S. Ahn, et al., “Effect of liquid spreading due to nano/microstructures on the critical heat flux during pool boiling,” Appl. Phys. Lett., vol. 98, p. 071908 2011 and M.-C. Lu, et al., “Critical heat flux of pool boiling on Si nanowire array-coated surfaces,” Int. J. Heat Mass Transfer, vol. 54, p. Int. J. Heat Mass Transfer, 2011), was achieved with a ΔT=39.3±1.8 K on S6. The results demonstrate the positive correlation between the CHF and surface roughness. In addition, the two nearly identical boiling curves for the smooth surface (Sm) demonstrate the consistency and accuracy of the measurements.

### CHF Model

To understand and predict CHF on structured surfaces where the liquid wets the surface completely, a model incorporating surface properties (i.e., surface roughness) is required. While a detailed understanding of the CHF mechanism is still lacking, it is clear that surface wettability is a key factor dictating CHF. See, for example, T. G. Theofanous, et al., “The boiling crisis phenomenon Part I: nucleation and nucleate boiling heat transfer,” Exp. Therm. Fluid Sci., vol. 26, pp. 775-792, 2002, C. Gerardi, et al., “Infrared thermometry study of nanofluid pool boiling phenomena,” Nanoscale Res. Lett., vol. 6, p. 232, 2011, S. G. Liter and M. Kaviany, “Pool-boiling CHF enhancement by modulated porous-layer coating: theory and experiment” Int. J. Heat Mass Tran., vol. 44, pp. 4287-4311, 2001, G. P. Narayan, et al., “Mechanism of enhancement/deterioration of boiling heat transfer using stable nanoparticle suspensions over vertical tubes.,” J. Appl. Phys., vol. 102, p. 074317, 2007, S. J. Kim, et al., “Surface wettability change during pool boiling of nanofluids and its effect on critical heat flux,” Int. J. Heat Mass Transfer, vol. 50, pp. 4105-4116, 2007, T. G. Theofanous and T.-N. Dinh, “High heat flux boiling and burnout as microphysical phenomena: mounting evidence and opportunities,” Multiphase Sci Technol., vol. 18, pp. 1-26, 2006, and T. G. Theofanous, et al., “The boiling crisis phenomenon Part II: dryout dynamics and burnout,” Exp. Therm. Fluid Sci., vol. 26, pp. 793-810, 2002, each of which is incorporated by reference in its entirety. Recent works have used the capillary pumping mechanism, which assumes that there is insufficient liquid supply to balance the rate of evaporation, to predict CHF on structured surfaces. See, for example, R. Chen, et al., “Nanowires for Enhanced Boiling Heat Transfer,” Nano Lett., vol. 9, pp. 548-553, Jan. 16, 2009 and S. G. Liter and M. Kaviany, “Pool-boiling CHF enhancement by modulated porous-layer coating: theory and experiment” Int. J. Heat Mass Tran., vol. 44, pp. 4287-4311, 2001, each of which is incorporated by reference in its entirety. However, this model over-predicted CHF values for the microstructured surfaces (17-120× greater than the experimental results), which suggests another mechanism dominates CHF in this case. Kandlikar presented a simplified force-based analysis for smooth surfaces assuming that there is sufficient liquid supply at CHF. Momentum, buoyancy, and surface forces at the liquid/vapor interface of an individual bubble were considered. See, for example, S. G. Kandlikar, “A Theoretical Model to Predict Pool Boiling CHF Incorporating Effects of Contact Angle and Orientation,” J. Heat Transfer, vol. 123, pp. 1071-1079, 2001, which is incorporated by reference in its entirety. If the combination of surface and buoyancy forces compensate the momentum force during the growth phase of the bubble, the hot/dry area developed at the base of bubble during growth can rewet upon departure. Otherwise, the hot/dry area will expand irreversibly leading to the CHF condition. See, for example, C. Gerardi, et al., “Infrared thermometry study of nanofluid pool boiling phenomena,” Nanoscale Res. Lett., vol. 6, p. 232, 2011 and T. G. Theofanous, et al., “The boiling crisis phenomenon Part II: dryout dynamics and burnout,” Exp. Therm. Fluid Sci., vol. 26, pp. 793-810, 2002, each of which is incorporated by reference in its entirety. However, in recent studies the data comparing the predictions of the Kandlikar model to the CHF behavior on structured surfaces was typically presented as a function of apparent liquid receding angle fl, which leads to crowding when β→0. See, for example, S. Kim, et al., “Effects of nano-fluid and surfaces with nano structure on the increase of CHF,” Exp. Therm Fluid Sci., vol. 34, pp. 487-495, May 2010 and H. S. Ahn, et al., “Effect of liquid spreading due to nano/microstructures on the critical heat flux during pool boiling,” Appl. Phys. Lett., vol. 98, p. 071908 2011, each of which is incorporated by reference in its entirety. This result is attributed to the fact that the model couples bubble geometry and the surface force through the macroscopic contact angle. See, for example, S. G. Kandlikar, “A Theoretical Model to Predict Pool Boiling CHF Incorporating Effects of Contact Angle and Orientation,” J. Heat Transfer, vol. 123, pp. 1071-1079, 2001, which is incorporated by reference in its entirety. Thus, on superhydrophilic surfaces the model cannot account for a wide variety of structured surfaces that display no apparent contact angle, i.e., β=0. See, for example, R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, and H. S. Ahn, et al., “Effect of liquid spreading due to nano/microstructures on the critical heat flux during pool boiling,” Appl. Phys. Lett., vol. 98, p. 071908 2011, which is incorporated by reference in its entirety.

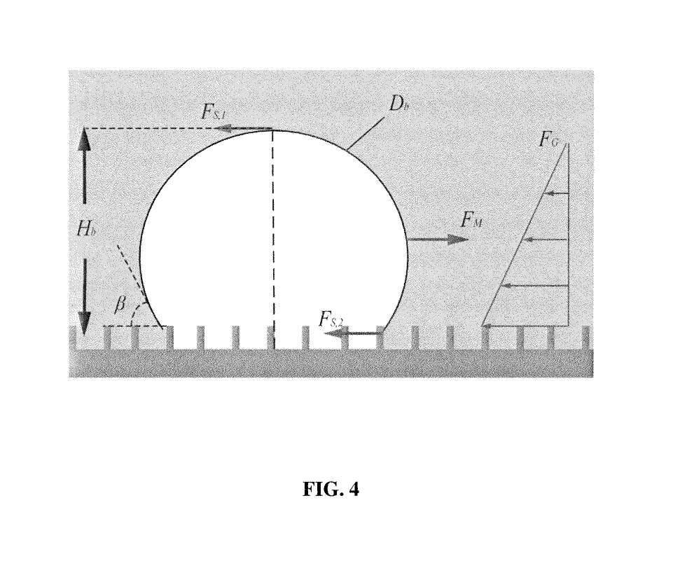

To address this issue, the force-balance-based model was modified to predict CHF on superhydrophilic surfaces (β=0). In this regime, the microlayer (which includes the structures) underneath the bubble dries out such that a “Wenzel” bubble (R. N. Wenzel, “Resistance of Solid Surfaces to Wetting by Water,” Ind. Eng. Chem., vol. 28, pp. 988-994, 1936, which is incorporated by reference in its entirety) is formed at CHF (C. Gerardi, et al., “Infrared thermometry study of nanofluid pool boiling phenomena,” Nanoscale Res. Lett., vol. 6, p. 232, 2011, which is incorporated by reference in its entirety) as shown in FIG. 4.

Referring to FIG. 4, a schematic diagram of horizontal forces acting on the vapor bubble on a structured surface adapted from Kandlika. At CHF, the vapor film forms within microstructures beneath the bubble, i.e., “Wenzel” bubble. Here F_{M} represents the force due to momentum change while F_{G} represents the buoyancy force, and F_{S,1} and F_{S,2} are surface forces. β is the apparent liquid receding angle on the structured surface, H_{b} is the height of the bubble and D_{b} is the diameter of the bubble

Therefore, the surface force per unit length maintaining the position of the contact line (i.e., F_{S,2} in FIG. 4) is amplified due to a longer effective contact line length, which can be estimated, assuming a bubble size larger than the underlying roughness length scale, as the unit length multiplied by the surface roughness,

F_{S,2}σₗᵥ×r cos θ_{rec}, (1)

where σₗᵥ is the liquid-vapor surface tension and θ_{rec} is the liquid receding angle on the corresponding smooth surface. CHF occurs when momentum force F_{M} is greater than the sum of surface forces F_{S,1}, F_{S,2}, and buoyancy force F_{G}. See, for example, S. G. Kandlikar, “A Theoretical Model to Predict Pool Boiling CHF Incorporating Effects of Contact Angle and Orientation,” J. Heat Transfer, vol. 123, pp. 1071-1079, 2001, which is incorporated by reference in its entirety. Therefore, at CHF, the force balance in horizontal direction yields

F_{M}=F_{S,1}+F_{S,2}+F_{G}. (2)

Following the set of assumptions introduced by Kandlikar, an expression for CHF was obtained in the following form:

q″_{c}=K×h_{fg}ρ_{g}^{1/2}[σₗᵥg(ρ₁−ρ_{g})]^{1/4}, (3)

Where

$$K = {( \frac{1 + cos β}{16} ) [ \frac{2 ( 1 + α )}{π ( 1 + cos β )} + \frac{π}{4} ( 1 + cos β ) cos ψ ]}^{1 / 2} ,$$

α=r cos θ_{rec}, h_{fg} is the latent heat, ρ_{g} is the vapor density, and φ is the inclined angle of surface (i.e., φ for a horizontal upward facing surface). Note that when α<1, Eq. 3 simplifies to Kandlikar's model. In this form, the surface force is no longer coupled with the bubble geometry such that Eq. 3 is well-defined in the complete wetting regime where cos β=1, but α>1.

To demonstrate the applicability of Eq. 3, the predicted CHF as a function of α was overlaid with data from the experiments and previous studies in FIG. 5. See, for example, R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, and H. S. Ahn, et al., “Effect of liquid spreading due to nano/microstructures on the critical heat flux during pool boiling,” Appl. Phys. Lett., vol. 98, p. 071908 2011, each of which is incorporated by reference in its entirety. Also plotted for comparison is the CHF predicted by the classical Kutateladze-Zuber (K-Z) model (N. Zuber, “Hydrodynamic Aspects of Boiling Heat Transfer,” AEC Report AECU-4439, 1959 and S. S. Kutateladze, “On the Transition to Film. Boiling under Natural Convection,” Kotloturbostroenie, vol. 3, pp. 10-12, 1948, each of which is incorporated by reference in its entirety) (hydrodynamic instability mechanism) using an empirical factor of K=0.18 in Eq. 3. See, for example, W. M. Rohsenow, et al., Handbook of heat transfer fundamentals, 2 ed. New York: McGraw-Hill, 1985, which is incorporated by reference in its entirety. The r values for Chen et al., Kim et al. and Ahn et al. were estimated based on the reported geometrical parameters and SEMs. These values may be inaccurate due to the fact that the surface roughness was, either, not explicitly reported or the calculation method was not detailed. In addition, contact angles reported in the literature are typically equilibrium values (θ_{eq}) measured at room temperature T_{α}. See, for example, R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, H. S. Ahn, et al., “Effect of liquid spreading due to nano/microstructures on the critical heat flux during pool boiling,” Appl. Phys. Lett., vol. 98, p. 071908 2011, and M.-C. Lu, et al., “Critical heat flux of pool boiling on Si nanowire array-coated surfaces,” Int. J. Heat Mass Transfer, vol. 54, p. Int. J. Heat Mass Transfer, 2011, each of which is incorporated by reference in its entirety. Since the surface wettability is a key parameter in determining CHF, the dependence of contact angle and surface tension on temperature should be accounted for. See, for example, S. G. Kandlikar, “A Theoretical Model to Predict Pool Boiling CHF Incorporating Effects of Contact Angle and Orientation,” J. Heat Transfer, vol. 123, pp. 1071-1079, 2001, C. Gerardi, et al., “Infrared thermometry study of nanofluid pool boiling phenomena,” Nanoscale Res. Lett., vol. 6, p. 232, 2011 and T. G. Theofanous and T.-N. Dinh, “High heat flux boiling and burnout as microphysical phenomena: mounting evidence and opportunities,” Multiphase Sci Technol., vol. 18, pp. 1-26, 2006, each of which is incorporated by reference in its entirety. Therefore, to compare the data with the CHF model, estimations for contact angles at the saturation temperature, Tₛₐₜ=100° C., are necessary. Here, the variation of cos 6 with temperature was estimated from the Young-Dupré equation (J. N. Israelachvili, Intermolecular and Surface Forces, 3 ed.: Elsevier, 2011, which is incorporate by reference in its entirety),

cos θ(T)=Wₗₛ/σₗᵥ(T)−1, (4)

where σₗᵥ(T) is the temperature-dependant liquid-vapor surface tension (E. W. Lemmon, et al., “NIST Standard Reference Database 23: Reference Fluid Thermodynamic and Transport Properties-REFPROP, Version 8.0,” ed. Gaithersburg, Md.: U.S. Department of Commerce, Technology Administration, National Institute of Standards and Technology, 2007, which is incorporated by reference in its entirety) and Wₗₛ, the work of adhesion between the liquid and solid, was estimated as

Wₗₛ≈2\sqrt{σₛᵥ^{d}σₗᵥ^{d}(T)} (5)

where σₛᵥ is the solid-vapor surface tension and the superscript, d, represents the dispersive component of surface tension. While σₛᵥ^{d} should be only a weak function of temperature, varying by less than 1% over the investigated range from ambient to saturated temperature, the strong temperature-dependent σₗᵥ^{d} is determined from detailed calculations. See, for example, S. Takeda, et al., “Surface OH group governing adsorption properties of metal oxide films,” Thin Solid Films, vol. 339 pp. 220-224, 1999, which is incorporated by reference in its entirety.

Referring to FIG. 5, a graph is presented depicting CHF as function of α(=r cos θ_{rec}). The proposed model (solid line) is compared to the Kutateladze-Zuber model with a factor of K=0.18 (W. M. Rohsenow, et al., Handbook of heat transfer fundamentals, 2 ed. New York: McGraw-Hill, 1985) (dashed line) which has been commonly accepted in the past. The symbols show the CHF data from () experiments presented here, (▾) Chen et al., (▴) Kim et al., and (□▪) Ahn et al. as a function of α. The hollow symbols show the data from literature (Chen et al., Kim et al., and Ahn et al.) while the solid symbols show the results adjusted using the estimation of θ_{rec}(Tₛₐₜ). The inset shows data from Kim et al. with surface roughness r˜50-55.

In FIG. 5, the symbols represent experimental results with estimated θ_{rec}(Tₛₐₜ) from literature (See, for example, R. Chen, et al., “Nanowires for Enhanced Boiling Heat Transfer,” Nano Lett., vol. 9, pp. 548-553, Jan. 16, 2009, S. Kim, et al., “Effects of nano-fluid and surfaces with nano structure on the increase of CHF,” Exp. Therm Fluid Sci., vol. 34, pp. 487-495, May 2010, and H. S. Ahn, et al., “Effect of liquid spreading due to nano/microstructures on the critical heat flux during pool boiling,” Appl. Phys. Lett., vol. 98, p. 071908 2011, each of which is incorporated by reference in its entirety) and the measurement (solid symbols) and results with θ_{rec}(T_{α}) (hollow symbols) as benchmark values. The difference in α between data from the literature and the estimates demonstrates the potential significance of temperature-to dependant liquid contact angle on the amplified surface force (Eq. 1). The error bars for the data along the α-axis are based on the uncertainty in the contact angle measurement at T_{α} while the error bars on α for the literature data are due to fact that only θ_{eq} is reported rather than θ_{rec}. For these cases, α was estimated using θ_{eq}/2 (i.e., average between θ_{eq} and 0) where the error in θ_{rec} ranged from θ_{eq} to 0. The error bars for CHF from Ahn et al. were not reported, and are therefore not shown in FIG. 5. Note that the estimated α values for the data of Kim et al. in the complete wetting regime are shown in the inset of FIG. 5 because of the very large estimated α values (α˜55) due to the large reported surface roughness for their nanostructures (r˜50) and the approximate nature of the temperature-dependent contact angle analysis. The wide error bars shown in the inset are due to the estimated error of the receding angle (ranging from θ_{eq} to 0) and the large reported roughness. The result highlights the importance of properly characterizing the wetting properties.

While the value of α has been approximated and simplifications in the extended model exist, the good agreement between the data and model, which does not contain any fitting parameters, suggests that the key physics of the CHF mechanism on these structured surfaces are accounted for. Most importantly, the trend of a small increase in CHF with increasing surface roughness, relative to the regime where α<1, is well-captured by the extended model. In addition, the sudden slope reduction predicted by the extended model at α=1 can explain how the K-Z model remains well-correlated to CHF behavior on a range of typical engineering surfaces studied in the past where α<1.5 (i.e., native metal oxide). The extended model also suggests that the CHF of ˜250 W/cm² is realizable when α is ˜11-12, which can be achieved by increasing the height of micropillar to 40-50 μm. However, the reduction in slope of the model for α>1 implies that a large increase in surface roughness is required to further enhance CHF, which offers significant fabrication challenges. One potential solution, as demonstrated by Kim et al., is the use of hierarchical structures comprised of multiple roughness length scales. Following the logic suggested by Eq. 1, the effective roughness of a hierarchical surface is estimated as the product of the roughness of each length scale (i.e., r_{eff}=Π₁ⁿr_{N}, where r_{N} is the roughness of each distinct length scale).

An enhancement in CHF of ˜160% and a CHF of ˜208 W/cm², which is comparable to the highest CHF value reported in previous studies on nanostructured surfaces, was demonstrated on the CMOS-compatible microstructured surfaces. To explain the experimental observations, an analytical force balance model was extended to predict CHF in the complete wetting regime. The model shows good agreement with the experimental observations which demonstrates the important effect of roughness-augmented wettability on CHF. The issues of contact angle variation with temperature were also addressed and should be considered in future studies given the nature of the CHF mechanism presented here. Furthermore, a hierarchical surface can be used to achieve ultra high CHF based on the model predication. This study shows new insight of the role of structured surfaces in enhancing CHF and suggests opportunities to tailor advanced surface technologies using CMOS-compatible processes to achieve high heat removal for high-power electronics cooling.

### Hierarchical Silica or CuO-Based Surfaces

In other circumstances, the surface can include highly-roughed, super-wetting hierarchical structures and multiple low surface energy (hydrophobic) spots. The super-wetting hierarchical structure can be comprised of multiple roughness length scales, ranging from hundreds micrometers to tens nanometers. The effective roughness of the proposed hierarchical surface can be estimated as the product of the roughness of each length scale (i.e., r_{eff}=Π₁^{N}r_{N}, where r_{N} is the roughness of each distinct length scale). Thus, the effective contact line length of liquid, vapor, and solid interface increases due to the high roughness of hierarchical structures. The roughness-augmented capillary force provides strong pumping power to maintain liquid supply to the local hot spot during phase change process and avoid local dryout condition. While the super-wetting hierarchical structures is used to enhance the capillary effect to increase the maximum heat dissipation capability, the low surface energy spots via, for example, surface treatment such as printing, e.g., micro contact printing (μCP) technique, provides low energy barrier for nucleation process during phase change, which effectively enhancement the heat transfer coefficient. The combination of these two effects increases the overall heat transfer performance.

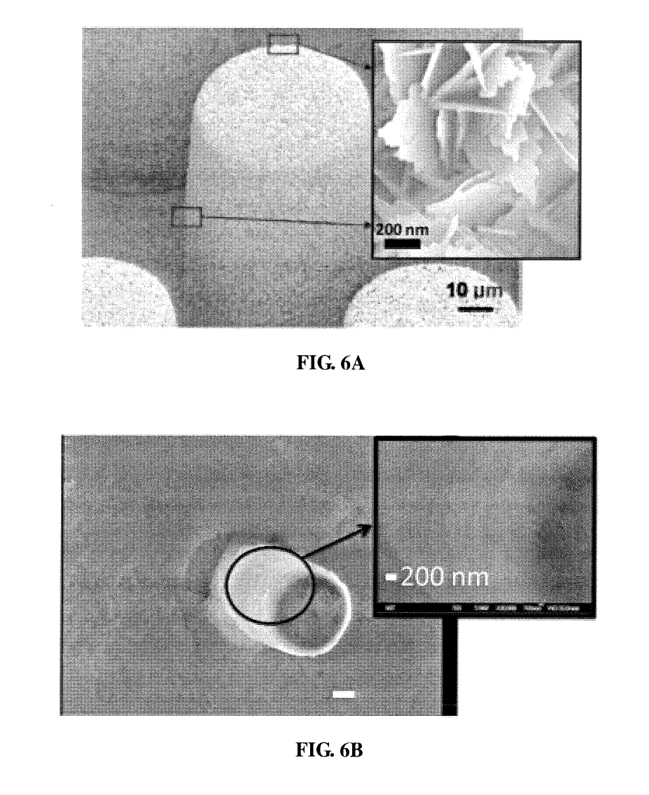

Referring to FIGS. 6A and 6B, scanning electron micrographs (SEMs) are shown for the example hierarchical surfaces created by (FIG. 6A) CuO nanostructure on Cu microposts, and (FIG. 6B) silica nanoparticles deposited on silicon microposts. FIG. 6A shows the CuO nanostructure made by the oxidation on the Cu microposts, which is fabricated using microfabrication. FIG. 6B shows the silica nanoparticles are deposited onto silicon microposts with electrophoretic deposition (EPD). The surfaces both show super-wetting behavior (contact angle ˜0 for water).

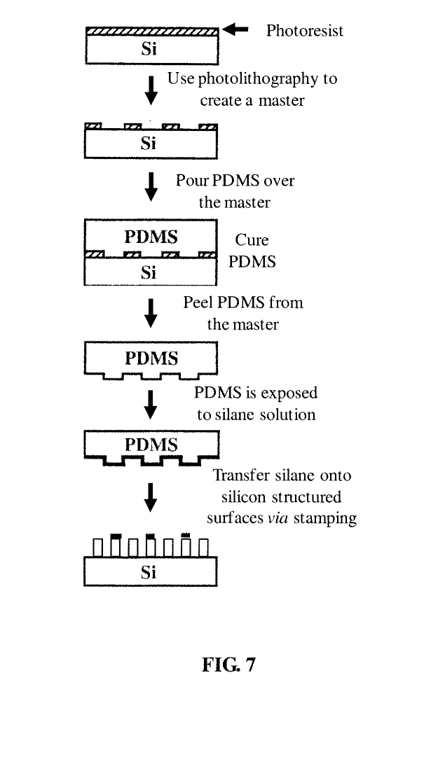

FIG. 7 represents a process flow to create low surface energy spots. For example, a polydimethylsiloxane (PDMS) stamp can be made to selectively deposit functional group onto the microstructured or nanostructured or hierarchically structured surfaces to create spots for preferential nucleation allowing for onset of boiling at low superheats.

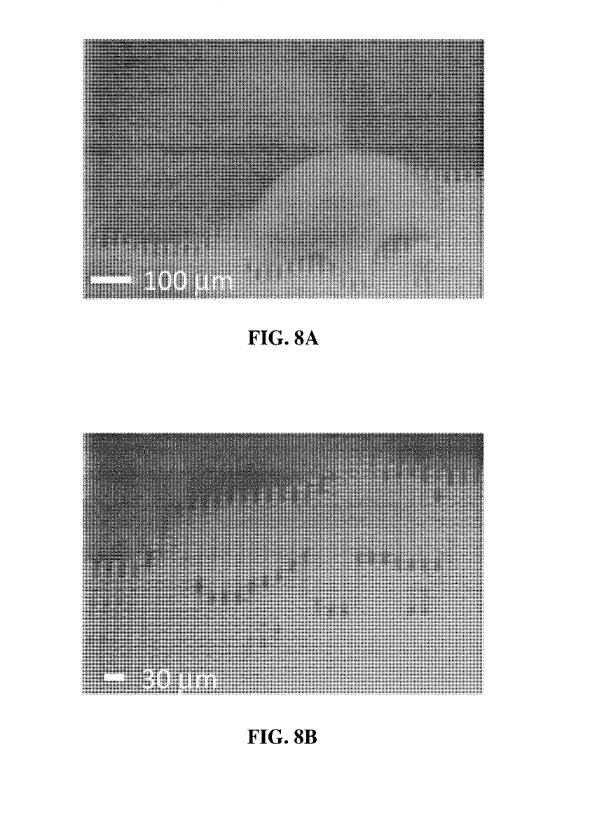

FIGS. 8A and 8B represent scanning electron micrographs (SEMs) of the superhydrophilic, SiO₂ microstructured surfaces with silane functionalization (tridecafluoro-1,1,2,2-tetrahydrooctyl)-1-trichlorosilane on the top of microposts using μCP. In FIG. 8A, the surface shows hydrophobic property on the top of microposts, where the contact angle of water is larger than 90°, while in FIG. 8B, the bottom surface and side wall of microposts maintain the hydrophilic property (contact angle <90°).

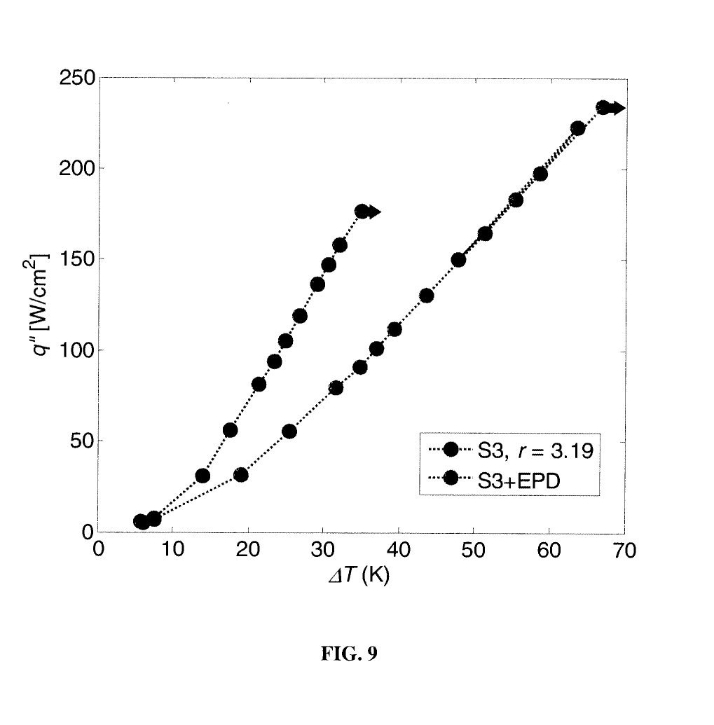

FIG. 9 shows the comparison of boiling curve (heat flux q″ versus super heat ΔT) of a microstructured surface (S3) and a hierarchical structured surface created by EPD technique (S3+EPD). The black arrows indicate the critical heat flux (CHF) condition. The results clearly show the better heat transfer performance (large CHF enhancement) with hierarchical surfaces over the microstructured surfaces.

### Fabrication and Boiling Setup

Both silica and copper oxide (CuO)-based hierarchical surfaces were fabricated with r≅3.6-13.3 to further increase CHF and support the concept that introducing hierarchy produces a multiplicative effect on contact line pinning forces. Accordingly, q_{c}″≅250 W/cm² was demonstrated on the roughest sample tested representing a ˜200% increase in CHF compared to smooth SiO₂ reference surfaces. The obtained CHF values on the hierarchical surfaces showed good agreement with the model prediction, which supports the physical view of the enhancement phenomenon and the multiplicative effect of roughness at distinct length scales. This predictable high heat removal capability using scalable fabrication techniques promises an exciting opportunity for new surface designs for high flux thermal management.

In the superhydrophilic wetting regime (β=0°, Eq. 3 shows a proportional increase in CHF with the parameter K, which, in turn, is proportional to the square root of the roughness factor r through α, i.e., q_{c}″∝✓r. Therefore, further enhancement in CHF should increase monotonically with increasing roughness factor. Indeed, experimental pool boiling data on microstructured surfaces with roughness factors r ranging from 1.8 to 6 has been demonstrated to follow this scaling, with reasonable quantitative agreement despite several simplifying assumptions used in the model development. See, K.-H. Chu, R. Enright, and E. N. Wang, Applied Physics Letters 100 (24), 241603 (2012), which is incorporated by reference in its entirety.

To achieve higher roughness factors, r >6, two fabrication methods were used to realize hierarchical surfaces with two distinct length scales. Silica-based, superhydrophilic hierarchical surfaces were fabricated by microstructuring silicon via deep reactive ion etching (DRIE) followed by the electrophoretic deposition (EPD) of 14 nm SiO₂ nanoparticles. Details of the EPD process can be found in previous work. See, Y. S. Joung and C. R. Buie, Langmuir 27 (7), 4156 (2011), which is incorporated by reference in its entirety. CuO-based, superhydrophilic hierarchical surfaces were fabricated by electroplating Cu micropillars followed by a chemical oxidation step to form CuO nanostructures. See, Y. Nam, S. Sharratt, C. Byon, S. J. Kim, and Y. S. Ju, JMEMS 19 (3), 581 (2010), which is incorporated by reference in its entirety. Scanning electron micrographs (SEMs) representative of the realized silica and CuO-based hierarchical surfaces are shown in FIGS. 10A-10F. FIG. 10A shows EPD-coated silica micropillar array. FIG. 10B shows CuO micropillar array. FIG. 10C the magnified view of the silica-based micropillar and EPD-coated SiO₂ nanoparticles (inset). FIG. 10D shows the magnified view of the CuO micropillar and CuO nanostructures formed on the surfaces (inset). (e) Cross-section view of the silica-based micropillar and (f) Crosssection view of the CuO micropillar obtained using FIB milling. Also, shown in FIGS. 10E and 10F are the crosssection images of the silica-based micropillar (FIG. 10E) and the CuO micropillar (FIG. 10F) hierarchical structures obtained using focused ion beam (FIB) milling. Finally, on all surfaces, a 1 μm thick layer of Cu was deposited on the back side of the silicon substrates to facilitate solder attachment of the samples to the test setup. Upon dicing, the samples had a projected surface area of 2×2 cm², which is large enough to be considered representative of an infinite plate (see, T. G. Theofanous, J. P. Tu, A. T. Dinh, and T. N. Dinh, Exp. Therm. Fluid Sci. 26 (6-7), 775 (2002), and M.-C. Lu, R. Chen, V. Srinivasan, V. P. Carey, and A. Majumdar, Int. J. Heat Mass Transfer 54 (25-26), 5359 (2011), each is which is incorporated by reference in its entirety), and is of comparable size to typical high heat flux electronic components. The heat transfer performance of the hierarchical surfaces was measured using an experimental pool boiling setup (FIG. 2). All tests were performed using degassed, high purity water (Chromasolv for HPLC, Sigma-Aldrich) to avoid premature bubble formation and minimize surface contamination.

To estimate the surface roughness factors r of the EPD-coated silica surfaces, the roughness factors of the nanoscale structure component, rₙ, was characterized using atomic force microscopy (AFM) and cross-section images by FIB milling. For the CuO surfaces, however, rₙ was difficult to measure by AFM due to the high aspect ratio of the CuO nanostructures and characteristic length of the spacing between the nanostructures and by cross-section imaging due to deposited byproduct of ablation on the surface during FIB milling process. Accordingly, the results using AFM, FIB images, and contact angle measurement may not reflect the condition that the vapor bubble is in contact with the surfaces (i.e., true contact line length). Therefore, the rₙ of the CuO nanostructures was extracted from CHF data obtained on a nanostructured CuO surface using the CHF model (Eq. 3). The effective rn on the CuO nanostructured surfaces estimated by this indirect approach was ˜4.8. The CuO nanostructures on both the smooth and microstructured Cu surfaces were formed using the same oxidation conditions. The total roughness factors, r, were then calculated as the product of rₙ and roughness factor of the micropillars rₘ (i.e., r=rₙ×rₘ). Both hierarchical surface types demonstrated superhydrophilic behavior at room temperature due to the large roughness factors obtained, r>6, and the high surface energy of SiO₂ and CuO.

### Experimental Results

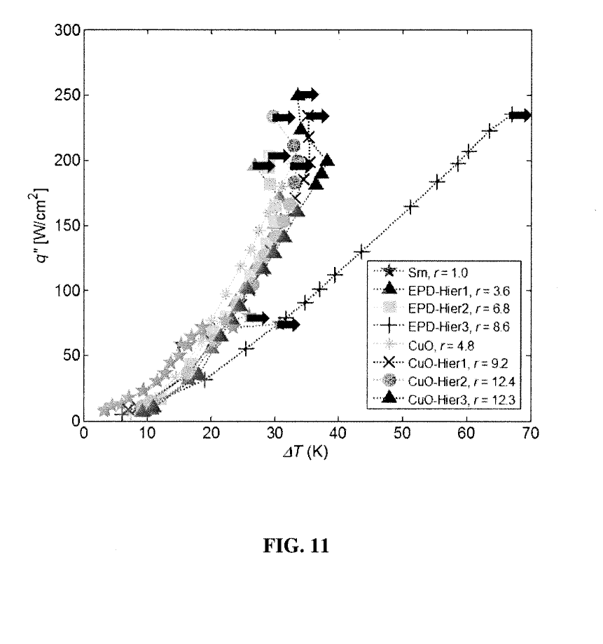

The heat flux q″ as a function of wall superheat ΔT=T_{w}−Tₛₐₜ, where T_{w} is the heated surface temperature and Tₛₐₜ is the saturation temperature (i.e. boiling curve), for Si-silica- and Cu—CuO-based hierarchical surfaces. Reference boiling curves obtained for smooth SiO₂ surfaces (r≅1) are also shown in FIG. 11 for comparison. The arrows indicate the CHF condition. The consistency and accuracy of the measurements are demonstrated by the two nearly identical boiling curves for the smooth surface. The boiling curves show a clear trend of increasing CHF with surface roughness due to roughness-augmented capillary forces. Details of the tested surface geometries are listed in Table II. The maximum uncertainty of the heat flux and temperature measurements was calculated to be ˜5.6% and ±1.8 K, respectively. While a CHF of ˜83 W/cm² was obtained on the smooth SiO₂ (Sm) surfaces, CHF values of 236 W/cm² and 249.2 W/cm2 were demonstrated on the best performing Si-silica (EPD-Hier3) and Cu—CuO-based (CuO-Hier3) hierarchical surfaces, respectively. The significant enhancement in CHF on the hierarchical surfaces (up to 200%) is attributed to the high surface roughness factor, which provides a large surface force to balance the momentum force due to evaporation. See Chu et al. (APL, 2011). In addition, the sudden reduction in superheat ΔT along the boiling curve of hierarchical surfaces (i.e., “kickback”) is indicative of nucleation sites within the nanostructures becoming active. The high roughness factor of the nanostructure on sample EPD-Hier3 was a result of the thick deposited silica layer (450 nm) due to a longer EPD deposition time (30 sec). See, V. P. Carey, Liquid-Vapor Phase Change Phenomena. (Taylor & Francis, Bristol, 1992), which is incorporated by reference in its entirety. However, the resulting thermal resistance due to the thick silica layer on sample EPD-Hier3 was estimated to be ˜2.5-13× higher than the nanostructure coatings on the other samples (EPD-Hier1-2, CuO, and CuO-Hier1). While similar characteristics were evident in all of the other hierarchical surface boiling curves, the boiling curve of the sample EPD-Hier3 demonstrated a low slope and a high superheat (ΔT≅68±3.8° C.) at CHF due to the high thermal resistance of the thick EPD coating, leading to a low heat transfer coefficient.

TABLE II
Geometric parameters of the hierarchical surfaces. The units
of height, diameter and (center-to-center) spacing are in microns
(μm). The roughness of contact line, r, the products of roughness factors
at micro and nanoscales, i.e., r = rₙ × rₘ.

| | | Diam- | Spac- | Thick- | | | |
|---|---|---|---|---|---|---|---|
| Sample | Height | eter | ing | ness | | | |
| No. | (h) | (d) | (s) | (t) | rₘ | rₙ | r |
| Sm | n/a | n/a | n/a | n/a | 1.0 | 1.0 | 1.0 |
| EPD-Hier1 | 20 | 10 | 15 | 0.15 | 2.01 | 1.9 | 3.8 |
| EPD-Hier1 | 20 | 10 | 5 | 0.15 | 3.79 | 1.9 | 7.2 |
| EPD-Hier1 | 20 | 5 | 10 | 0.45 | 2.40 | 3.7 | 8.9 |
| CuO | n/a | n/a | n/a | 1 | 1.0 | 4.8* | 4.8 |
| CuO-Hier1 | 35 | 30 | 30 | 1 | 1.91 | 4.8* | 9.2 |
| CuO-Hier2 | 61 | 30 | 30 | 1 | 2.59 | 4.8* | 12.4 |
| CuO-Hier3 | 68 | 35 | 30 | 1 | 2.78 | 4.8* | 13.3 |

*Estimation based on the CHF model and experimental CHF values on CuO nanostructured surfaces

### DHF Model

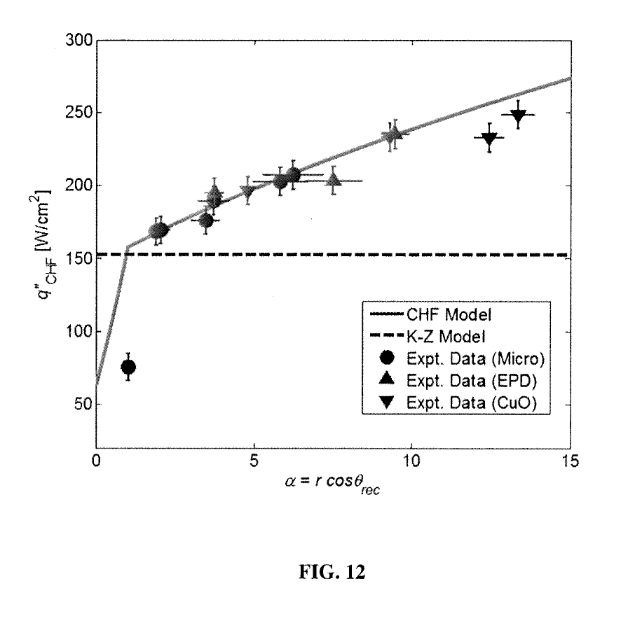

In FIG. 12, the predicted CHF as a function of a (Eq. 3) is overlaid with data from experiments for the hierarchical surfaces (in red) and previously tested microstructured surfaces (Chu et al. (APL, 2012), in blue). The dashed line represents the CHF predicted by the classical K-Z model (hydrodynamic instability mechanism) using an empirical factor of K=0.18 in Eq. 3 obtained from classical pool boiling experiments on unstructured, well-wetting surfaces (α≅1). The good agreement between the data and model, which does not contain any fitting parameters, for a ranging from 1 to ˜13.3 demonstrates the validity of the model (solid line) for the structured surfaces in the complete wetting regime. The trend of increasing CHF with increasing surface roughness is well-captured by the model which suggests that the key physics of the CHF mechanism on these structured surfaces were accounted for. While the value of rₙ of the CuO surfaces was approximated based on the CHF model and experimental data of CuO nanostructured surfaces, the agreement between the CHF on CuO hierarchical surfaces (CuO-Hier1-3) and the model prediction was consistent, suggesting that the effective surface roughness pinning the vapor bubble based on the indirect approach for the CuO nanostructured surfaces provided a reasonable estimation.

Hierarchically-structured surfaces were fabricated using electrophoretic deposition on microstructured silicon, and electroplated and oxidized copper with roughness factor, r of ˜3.6-13.3 to investigate the CHF conditions on high roughness factor surfaces in pool boiling. The excellent agreement between the CHF model and experimental observations on the hierarchical surfaces indicates that the roughness-amplified surface force plays the defining role in CHF enhancement on structured surfaces with a roughness factor r ranging from 1-13.3 with distinct roughness length scales introducing a multiplicative effect on the amplified surface force. A CHF of 249.2 W/cm² (i.e., a ˜200% CHF enhancement compared to smooth SiO₂ surfaces) achieved on CuO-based hierarchical surfaces demonstrates high heat removal capability. While the thick EPD-coated silica hierarchical surfaces have a high surface roughness factor, the high thermal resistance presents challenges with this approach for practical implementation. CuO hierarchical surfaces, on the other hand, can provide high roughness factors without a significant increase in thermal resistance. This finding highlights the importance of the surface structure thermal characteristics resulting from a particular synthesis technique so that enhanced CHF can be obtained without sacrificing heat transfer performance. Furthermore, the scalable fabrication process of electroplating copper micropillars coupled with a simple chemical oxidation process promises an exciting opportunity to achieve high performance boiling heat transfer.

Other embodiments are within the scope of the following claims.

What is claimed is:

1. A method of increasing heat removal capability of a surface comprising:
increasing surface roughness of a surface having a plurality of microstructured features to enhance surface wettability, whereby the critical heat flux of the surface is increased by at least 150%.

2. The method of claim 1, wherein the critical heat flux is at least 200 W/cm².

3. The method of claim 1, wherein the microstructured features include a plurality of micropillars.

4. The method of claim 3, wherein each of the plurality of micropillars has a diameter of 5 to 10 micrometers, a height of 10 to 20 micrometers, and neighboring micropillars of the plurality have center-to-center spacings of 5 to 15 micrometers.

5. The method of claim 1, wherein the roughness is at least 3.

6. The method of claim 1, wherein the roughness is at least 5.

7. The method of claim 1, wherein the surface includes a material selected from the group consisting of silicon, silica, copper, copper oxide and aluminum.

8. The method of claim 1, further comprising applying a surface modifying layer on at least a portion of surface.

9. The method of claim 8, wherein applying a surface modifying layer includes contact printing the surface with a surface modifying compound.

10. The method of claim 9, wherein the surface modifying compound includes a hydrophobic silane.

11. The method of claim 1, wherein the critical heat flux of the surface is increased by at least 160%.

12. A structure comprising:
a surface having a plurality of microstructured features and a hydrophilic surface roughening layer suitable to enhance surface wettability, whereby the critical heat flux of the surface is increased by at least 150%.

13. The structure of claim 12, wherein the critical heat flux is at least 200 W/cm².

14. The structure of claim 12, wherein the microstructured features include a plurality of micropillars.

15. The structure of claim 14, wherein each of the plurality of micropillars has a diameter of 5 to 10 micrometers, a height of 10 to 20 micrometers, and neighboring micropillars of the plurality have center-to-center spacings of 5 to 15 micrometers.

16. The structure of claim 12, wherein the roughness is at least 3.

17. The structure of claim 12, wherein the roughness is at least 5.

18. The method of claim 12, wherein the surface is made of a material selected from the group consisting of silicon, silica, copper, copper oxide and aluminum.

19. The structure of claim 12, wherein a portion of the surface includes a surface modifying layer including a surface modifying compound.

20. The structure of claim 19, wherein the surface modifying compound includes a hydrophobic silane.

21. The structure of claim 12, wherein the critical heat flux of the surface is increased by at least 160%.

22. A method of increasing heat removal capability of a surface comprising:
increasing surface roughness of a surface having a plurality of hierarchical features to enhance surface wettability, whereby the critical heat flux of the surface is increased by at least 150%.

23. The method of claim 22, wherein the surface is a silica surface.

24. The method of claim 23, wherein the silica surface is modified by electrophoretic deposition (EPD) of a plurality of silica nanoparticles.

25. The method of claim 23, wherein the critical heat flux is at least 200 W/cm².

26. The method of claim 22, wherein the roughness is at least 3.

27. The method of claim 22, wherein the roughness is at least 8.

28. The method of claim 22, wherein the surface is a copper oxide-based surface.

29. The method of claim 28, wherein the copper oxide-based surface is modified by electroplating of a plurality of copper micropillars.

30. The method of claim 28, wherein the critical heat flux is at least 250 W/cm².

31. The method of claim 22, wherein the roughness is at least 9.

32. The method of claim 22, wherein the roughness is at least 13.

33. The method of claim 22, further comprising applying a surface modifying layer on at least a portion of surface.

34. The method of claim 33, wherein applying a surface modifying layer includes contact printing the surface with a surface modifying compound.

35. The method of claim 34, wherein the surface modifying compound includes a hydrophobic silane.

36. The method of claim 22, wherein the critical heat flux of the surface is increased by at least 200%.

37. A structure of increasing heat removal capability of a surface comprising:
increasing surface roughness of a surface having a plurality of hierarchical features to enhance surface wettability, whereby the critical heat flux of the surface is increased by at least 150%.

38. The structure of claim 37, wherein the surface is a silica surface.

39. The structure of claim 38, wherein the silica surface is modified by electrophoretic deposition (EPD) of a plurality of silica nanoparticles.

40. The structure of claim 38, wherein the critical heat flux is at least 200 W/cm².

41. The structure of claim 37, wherein the roughness is at least 3.

42. The structure of claim 37, wherein the roughness is at least 8.

43. The structure of claim 37, wherein the surface is a copper oxide (CuO)-based surface.

44. The structure of claim 43, wherein the CuO-based surface is modified by electroplating of a plurality of Cu micropillars.

45. The structure of claim 43, wherein the critical heat flux is at least 250 W/cm².

46. The structure of claim 37, wherein the roughness is at least 9.

47. The structure of claim 37, wherein the roughness is at least 13.

48. The structure of claim 37, wherein a portion of surface includes a surface modifying layer including a surface modifying compound.

49. The structure of claim 48, wherein the surface modifying compound includes a hydrophobic silane.

50. The structure of claim 37, wherein the critical heat flux of the surface is increased by at least 200%.
